(19) United States
(12) Patent Application Publication
(10) Pub. No.: US 2026/0076099 A1
(43) Pub. Date: Mar. 12, 2026

(54) MAGNETORESISTIVE RANDOM ACCESS MEMORY AND METHOD FOR FABRICATING THE SAME

(71) Applicant: UNITED MICROELECTRONICS CORP., Hsin-Chu City (TW)

(72) Inventors: Hui-Lin Wang, Taipei City (TW); Hsiang-Chi Chien, Pingtung County (TW); Che-Wei Chang, Taichung City (TW); Chen-Yi Weng, New Taipei City (TW)

(73) Assignee: UNITED MICROELECTRONICS CORP., Hsin-Chu City (TW)

(21) Appl. No.: 18/916,732

(22) Filed: Oct. 16, 2024

(30) Foreign Application Priority Data
Sep. 9, 2024 (TW) 113134047

(51) Int. Cl. H10N 50/80; H10B 61/00; H10N 50/01; H10N 50/10

(52) U.S. Cl. CPC H10N 50/80; H10B 61/00; H10N 50/01; H10N 50/10

(57) ABSTRACT

A method for fabricating a magnetoresistive random access memory (MRAM) device includes the steps of first forming an inter-metal dielectric (IMD) layer on a substrate, forming a first metal interconnection and a second metal interconnection in the IMD layer, forming a spin orbit torque (SOT) layer on the first metal interconnection and the second metal interconnection, forming a magnetic tunneling junction (MTJ) on the SOT layer, forming a top electrode (TE) on the MTJ, and forming a cap layer on the MTJ and the SOT layer. Preferably, a bottom surface of the MTJ includes a first curve.

### BACKGROUND OF THE INVENTION

### 1. Field of the Invention

The invention relates to a magnetoresistive random access memory (MRAM) and method for fabricating the same.

### 2. Description of the Prior Art

Magnetoresistance (MR) effect has been known as a kind of effect caused by altering the resistance of a material through variation of outside magnetic field. The physical definition of such effect is defined as a variation in resistance obtained by dividing a difference in resistance under no magnetic interference by the original resistance. Currently, MR effect has been successfully utilized in production of hard disks thereby having important commercial values. Moreover, the characterization of utilizing GMR materials to generate different resistance under different magnetized states could also be used to fabricate MRAM devices, which typically has the advantage of keeping stored data even when the device is not connected to an electrical source.

The aforementioned MR effect has also been used in magnetic field sensor areas including but not limited to for example electronic compass components used in global positioning system (GPS) of cellular phones for providing information regarding moving location to users. Currently, various magnetic field sensor technologies such as anisotropic magnetoresistance (AMR) sensors, GMR sensors, magnetic tunneling junction (MTJ) sensors have been widely developed in the market. Nevertheless, most of these products still pose numerous shortcomings such as high chip area, high cost, high power consumption, limited sensibility, and easily affected by temperature variation and how to come up with an improved device to resolve these issues has become an important task in this field.

### SUMMARY OF THE INVENTION

According to an embodiment of the present invention, a method for fabricating a magnetoresistive random access memory (MRAM) device includes the steps of first forming an inter-metal dielectric (IMD) layer on a substrate, forming a first metal interconnection and a second metal interconnection in the IMD layer, forming a spin orbit torque (SOT) layer on the first metal interconnection and the second metal interconnection, forming a magnetic tunneling junction (MTJ) on the SOT layer, forming a top electrode (TE) on the MTJ, and forming a cap layer on the MTJ and the SOT layer. Preferably, a bottom surface of the MTJ includes a first curve.

According to another aspect of the present invention, a magnetoresistive random access memory (MRAM) device includes a spin orbit torque (SOT) layer on a substrate and a magnetic tunneling junction (MTJ) on the SOT layer. Preferably, a bottom surface of the MTJ includes a first curve.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 illustrate a method for fabricating a MRAM device according to an embodiment of the present invention.

FIG. 7 illustrates a structural view of a MRAM device according to an embodiment of the present invention.

### DETAILED DESCRIPTION

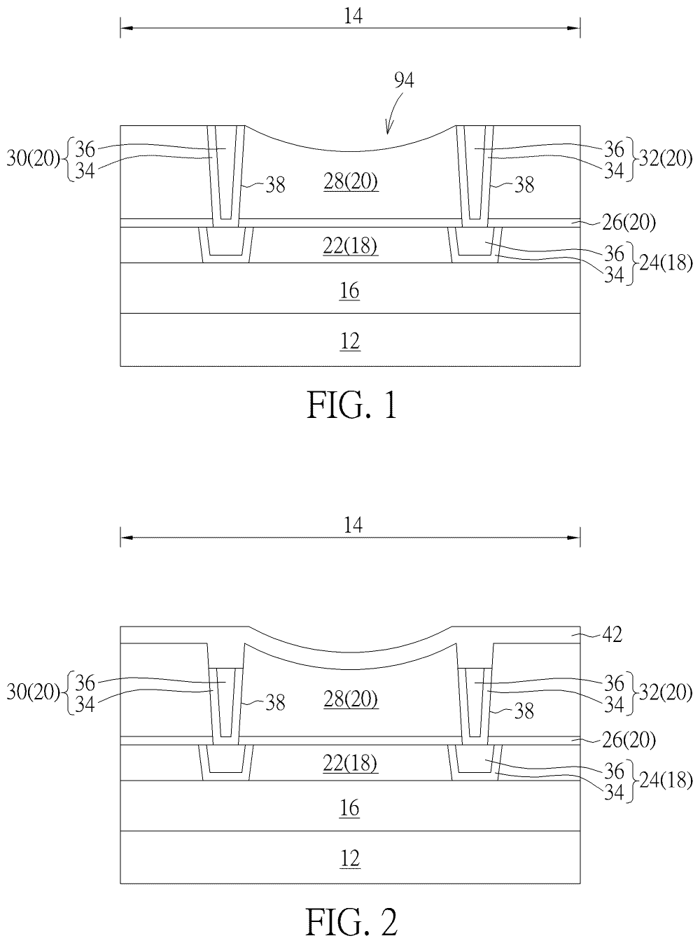

Referring to FIGS. 1-6, FIGS. 1-6 illustrate a method for fabricating a semiconductor device, or more specifically a MRAM device according to an embodiment of the present invention. As shown in FIG. 1, a substrate 12 made of semiconductor material is first provided, in which the semiconductor material could be selected from the group consisting of silicon (Si), germanium (Ge), Si—Ge compounds, silicon carbide (SiC), and gallium arsenide (GaAs), and a MRAM region 14 and a logic region (not shown) are defined on the substrate 12.

Active devices such as metal-oxide semiconductor (MOS) transistors, passive devices, conductive layers, and interlayer dielectric (ILD) layer 16 could also be formed on top of the substrate 12. More specifically, planar MOS transistors or non-planar (such as FinFETs) MOS transistors could be formed on the substrate 12, in which the MOS transistors could include transistor elements such as gate structures (for example metal gates) and source/drain region, spacer, epitaxial layer, and contact etch stop layer (CESL). The ILD layer 16 could be formed on the substrate 12 to cover the MOS transistors, and a plurality of contact plugs could be formed in the ILD layer 16 to electrically connect to the gate structure and/or source/drain region of MOS transistors. Since the fabrication of planar or non-planar transistors and ILD layer is well known to those skilled in the art, the details of which are not explained herein for the sake of brevity.

Next, metal interconnect structures 18, 20 are sequentially formed on the ILD layer 16 to electrically connect the aforementioned contact plugs, in which the metal interconnect structure 18 includes an inter-metal dielectric (IMD) layer 22 and metal interconnections 24 embedded in the IMD layer 22, and the metal interconnect structure 20 includes a stop layer 26, an IMD layer 28, and metal interconnections 30, 32 embedded in the stop layer 26 and the IMD layer 28.

In this embodiment, each of the metal interconnections 24 from the metal interconnect structure 18 preferably includes a trench conductor and each of the metal interconnections 30, 32 from the metal interconnect structure 20 includes a via conductor. Preferably, each of the metal interconnections 24, 30, 32 from the metal interconnect structures 18, 20 could be embedded within the IMD layers 22, 28 and/or stop layer 26 according to a single damascene process or dual damascene process. For instance, each of the metal interconnections 24, 30, 32 could further include a barrier layer 34 and a metal layer 36, in which the barrier layer 34 could be selected from the group consisting of titanium (Ti), titanium nitride (TiN), tantalum (Ta), and tantalum nitride (TaN) and the metal layer 36 could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity. In this embodiment, the metal layers 36 in the metal interconnections 24 are preferably made of copper, the metal layers 36 in the metal interconnections 30, 32 are preferably made of tungsten, the IMD layers 22, 28 are preferably made of silicon oxide or ultra low-k (ULK) dielectric layer, and the stop layers 26 is preferably made of nitrogen doped carbide (NDC), silicon nitride, silicon carbon nitride (SiCN), or combination thereof.

Specifically, the formation of the metal interconnections 30, 32 at this stage could be accomplished by first using a photo-etching process to remove part of the IMD layer 28 for forming contact holes 38 exposing the metal interconnections 24 underneath, depositing the barrier layer 34 and metal layer 36 into the contact holes 38, and then conducting a planarizing process such as a chemical mechanical polishing (CMP) process to remove part of the metal layer 36 and part of the barrier layer 34 for forming metal interconnections 30, 32. It should be noted that fabrication parameters could be adjusted during removal of part of the metal layer 36 and part of the barrier layer 34 to form metal interconnections 30, 32 to result in over polish so that a recess 94 or indentation could be formed at relatively central region of the IMD layer 28 between the metal interconnections 30, 32 as a result of dishing phenomenon.

It should also be noted that in addition to using over polishing to form the recess 94, another approach of the present invention could first use a CMP process to over polish the surface of the IMD layer 28 and then conduct an extra etching process to increase the depth of the recess 94, which is also within the scope of the present invention. According to an embodiment of the present invention, the bottom surface of the recess 94 is slightly lower than top surface of the metal interconnections 30, 32 on two adjacent sides, in which the depth of the recess 94 could be between 5% to 50% of the overall height of the metal interconnections 30, 32 or most preferably between 10% to 30% of the overall height of the metal interconnections 30, 32.

Next, as shown in FIG. 2, a bottom electrode (BE) 42 is formed on the IMD layer 28 and a planarizing process such as chemical mechanical polishing (CMP) process is conducted to remove part of the BE 42 so that the thickness of the BE 42 is slightly reduced but still covering the entire top surface of the IMD layer 28. In this embodiment, the BE 42 preferably includes metal or metal nitride such as but not limited to for example tantalum (Ta) or tantalum nitride (TaN).

It should be noted that during the formation of the BE 42, an etching process could be conducted by using another patterned mask or the etching selectivity between the metal interconnections 30, 32 and the IMD layer 28 without additional patterned mask to remove part of the metal interconnections 30, 32 for forming recesses (not shown) directly on top of the metal interconnections 30, 32. Next, the BE 42 is formed in the recesses directly on top of the metal interconnections 30, 32 and on the IMD layer 28, and then the aforementioned planarizing process is conducted to remove part of the BE 42. Since the BE 42 is filled into the recesses directly on top of the metal interconnections 30, 32, the BE 42 formed at this stage if viewed from a cross-section perspective preferably includes a reverse U-shape cross-section, which mainly includes the BE 42 directly on top of the IMD layer 28 and BE 42 directly on top of the metal interconnections 30, 32 on two adjacent sides.

It should further be noted that since the top surface of central region of the IMD layer 28 is slightly lower than the top surface of the IMD layer 28 closer to two adjacent sides as a result of dishing phenomenon caused during formation of the metal interconnections 30, 32, after the BE 42 is formed on the surface of the IMD layer 28, not only the surface of the IMD layer 28 includes a curve concave upward, each of the bottom surface and top surface of the BE 42 also includes a curve concave upward. Moreover, the valley point or lowest point of the curve of the BE 42 between the metal interconnections 30, 32 could be slightly lower than or slightly higher than the bottom surface of the BE 42 directly on top of the metal interconnections 30, 32.

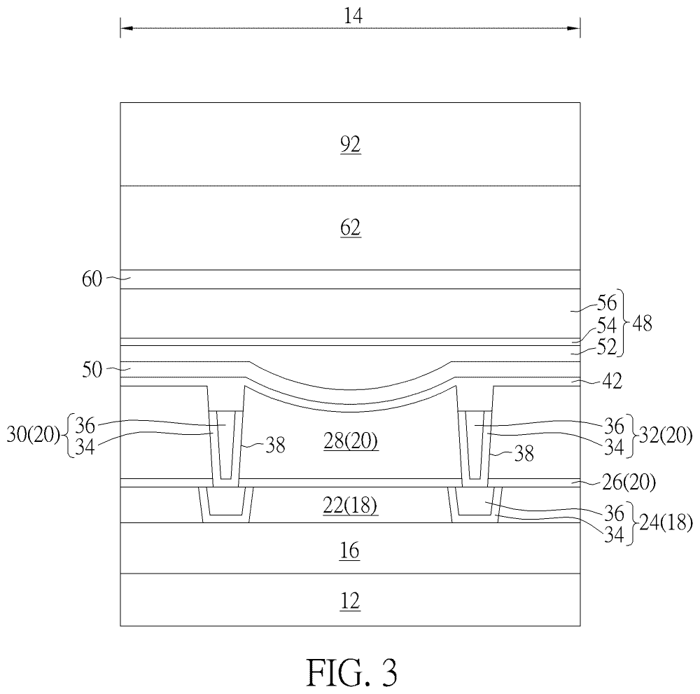

Next, as shown in FIG. 3, a spin orbit torque (SOT) layer 50 is formed on the surface of the BE 42, a MTJ stack 48 is formed on the SOT layer 50, and then a cap layer 60, a top electrode (TE) 62, and a hard mask 92 are formed on the MTJ stack 48.

In this embodiment, the formation of the MTJ stack 48 could be accomplished by sequentially depositing a free layer 52, a barrier layer 54, and a pinned layer 56 on the SOT layer 50. Preferably, the free layer 52 could be made of ferromagnetic material including but not limited to for example iron, cobalt, nickel, or alloys thereof such as cobalt-iron-boron (CoFeB), in which the magnetized direction of the free layer 52 could be altered freely depending on the influence of outside magnetic field. The barrier layer 54 could be made of insulating material including but not limited to for example oxides such as aluminum oxide (AlOₓ) or magnesium oxide (MgO). The pinned layer 56 could be made of antiferromagnetic (AFM) material including but not limited to for example ferromanganese (FeMn), platinum manganese (PtMn), iridium manganese (IrMn), nickel oxide (NiO), or combination thereof, in which the pinned layer 56 is formed to fix or limit the direction of magnetic moment of adjacent layers. It should be noted that since the present embodiment pertains to fabricating a SOT MRAM device, the free layer 52 is preferably disposed on the bottommost layer to contact the SOT layer 50 directly.

Preferably, the SOT layer 50 is serving as a channel for the MRAM device as the SOT layer 50 could include metals such as tantalum (Ta), tungsten (W), platinum (Pt), or hafnium (Hf) and/or topological insulator such as bismuth selenide (BiₓSe₁₋ₓ). The cap layer 60 preferably includes metal such as Ta and the TE 62 preferably includes conductive material such as metal or metal nitride, in which metal could include Ti whereas metal nitride could include TiN. Nevertheless, the cap layer 60 or TE 62 could all include conductive or dielectric material including but not limited to for example Ta, TaN, Ti, TiN, Pt, Cu, Au, Al, or combination thereof. The hard mask 92 could include dielectric material such as silicon oxide, but not limited thereto.

It should be noted that since both the bottom surface and top surface of the BE 42 formed in FIG. 2 include curved surfaces, after the SOT layer 50 and the MTJ stack 48 are formed on the BE 42, the bottom surface of the SOT layer 50 and the bottom surface of the MTJ stack 48 also include curved surfaces. Specifically, after the MTJ stack 48 is formed, the bottom surface of the SOT layer 50 includes a curved surface, the top surface of the SOT layer 50 includes a curved surface, and the bottom surface of the MTJ stack 48 also includes a curved surface. Even though the bottommost surface of the MTJ stack 48 such as the bottom surface of the free layer 52 includes a curved surface, the surfaces of the layers above the free layer 52 gradually become planar as the number of layers stacks up above the free layer 52. According to an embodiment of the present invention, one or more planarizing process such as CMP could be conducted after the free layer 52 is formed to ensure that both bottom and top surfaces of every material layer atop the free layer 52 has a planar surface, which is also within the scope of the present invention. For instance, the top surface of the free layer 52, bottom and top surfaces of the barrier layer 54, bottom and top surfaces of the pinned layer 56, bottom and top surfaces of the cap layer 60, and bottom and top surfaces of the TE 62 could all include planar surfaces.

Alternatively, in contrast to all material layers above the free layer 52 maintain planar bottom and top surfaces, according to another embodiment of the present invention, it would also be desirable to change the surface profile of the layers above the free layer 52 including the barrier layer 54, the pinned layer 56, the cap layer 60, and/or the TE 62 to have same profile such as a curved surface concave upward as the bottom surface of the free layer 52. For instance, either one or all of the top surface of the free layer 52, the top surface of the barrier layer 54, the top surface of the pinned layer 56, the top surface of the cap layer 60, and/or the top surface of the TE 62 could include a curve concave upward, which are all within the scope of the present invention.

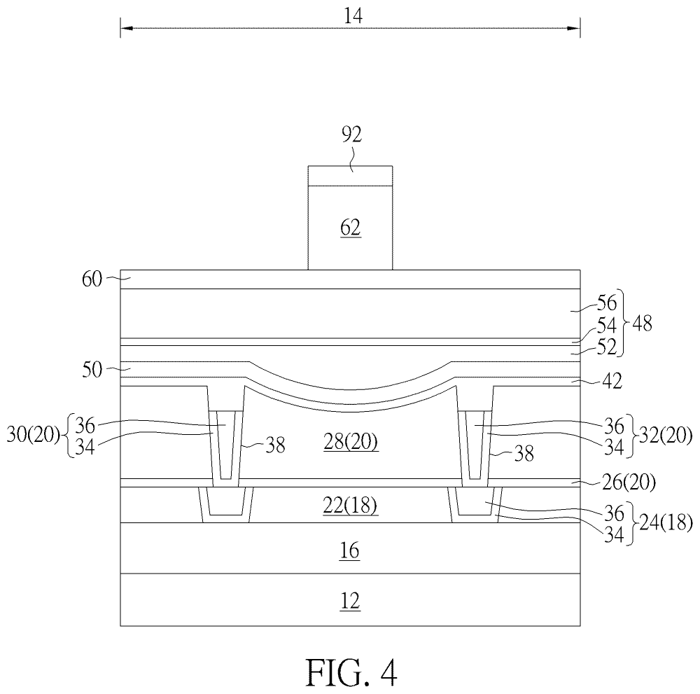

Next, as shown in FIG. 4, an etching process such as a reactive ion etching (RIE) process is conducted by using a patterned mask such as patterned resist (not shown) as mask to remove part of the hard mask 92 and part of the TE 62 for forming a patterned hard mask 92 and patterned TE 62.

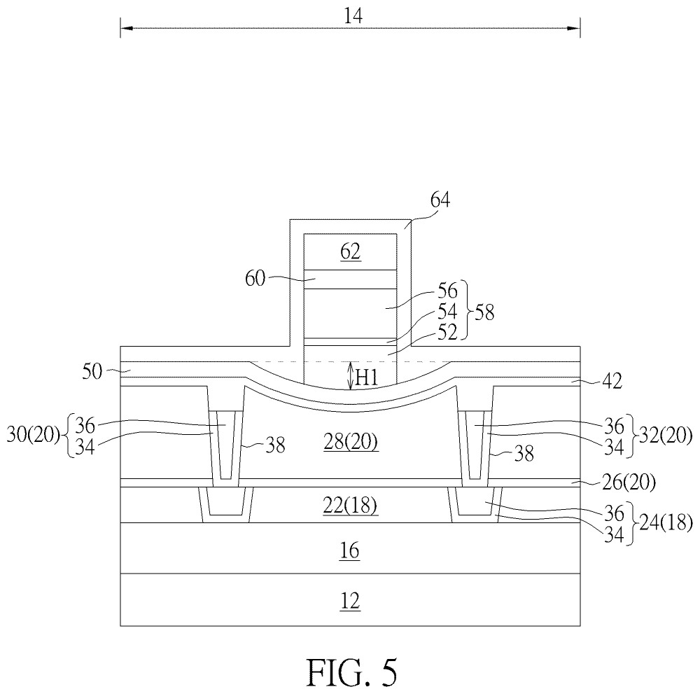

Next, as shown in FIG. 5, after removing the patterned hard mask 92, one or more etching process such as a RIE or ion beam etching (IBE) process is conducted by using the patterned TE 62 as mask to remove part of the cap layer 60, part of the MTJ stack 48, and even part of the SOT layer 50 for forming a MTJ 58 on the SOT layer 50. Next, a cap layer 64 is formed on the surface of the TE 62, MTJ 58, and SOT layer 50. In this embodiment, the SOT layer 50 could be etched or not etched during the patterning of the MTJ stack 48 so that after the MTJ 58 is formed, the top surface of the SOT layer 50 directly under the MTJ 58 could be even with or slightly higher than the top surface of the SOT layer 50 adjacent two sides of the MTJ 58, which are all within the scope of the present invention. Preferably, the cap layer 64 is made of nitrogen doped carbide (NDC), silicon nitride (SiN), silicon carbon nitride (SiCN), or combination thereof and most preferably made of SiN.

Since the bottom surface of the TE 42, the bottom surface of the SOT layer 50, and the bottom surface of the MTJ stack 48 all include curved surfaces as shown in FIG. 3, after the MTJ 58 is formed, bottom surface of the SOT layer 50, top surface of the SOT layer 50, and bottom surface of the MTJ 58 all maintain a curvy profile. The top surface of the MTJ 58, bottom surface of the TE 62, and top surface of the TE 62 on the other hand remain to be planar surfaces. Moreover, since the top surface of the IMD layer 28 is formed into a curved surface concave upward so that the bottom of the MTJ 58 or bottom of the free layer 52 is now slightly lower than the top surface of the metal interconnections 30, 32 or top surface of the SOT layer 50 on two adjacent sides, a height H1 is measured between the bottom surface of the MTJ 58 and the top surface of the SOT layer 50 directly on top of the metal interconnections 30, 32 adjacent to two sides of the MTJ 58 at this stage. In this embodiment, H1 is preferably between 10-30 Angstroms.

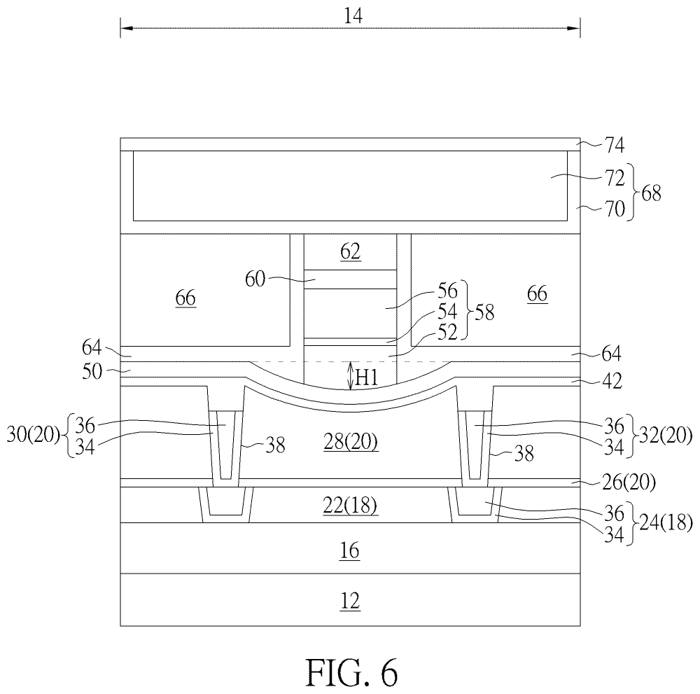

Next, as shown in FIG. 6, an IMD layer 66 is formed on the cap layer 64 and one or more photo-etching process is conducted to remove part of the IMD layer 66 and part of the cap layer 64 to form at least a contact hole (not shown) exposing the TE 62. Next, conductive materials are deposited into the contact hole and a planarizing process such as CMP is conducted to form a metal interconnection 68 connecting the TE 62 underneath, and another stop layer 74 is formed on the surface of the metal interconnection 68 thereafter. Similar to the aforementioned metal interconnections 24, the metal interconnection 68 could be embedded within the IMD layer 66 according to a single damascene process or dual damascene process. For instance, the metal interconnection 68 could further include a barrier layer 70 and a metal layer 72, in which the barrier layer 70 could be selected from the group consisting of titanium (Ti), titanium nitride (TiN), tantalum (Ta), and tantalum nitride (TaN) and the metal layer 72 could be selected from the group consisting of tungsten (W), copper (Cu), aluminum (Al), titanium aluminide (TiAl), and cobalt tungsten phosphide (CoWP).

In this embodiment, the IMD layer 66 preferably include an ultra low-k (ULK) dielectric layer including but not limited to for example porous material or silicon oxycarbide (SiOC) and the stop layer 74 preferably includes nitrogen doped carbide (NDC), silicon nitride (SiN), silicon carbon nitride (SiCN), or combination thereof and most preferably includes SiN. This completes the fabrication of a semiconductor device according to an embodiment of the present invention.

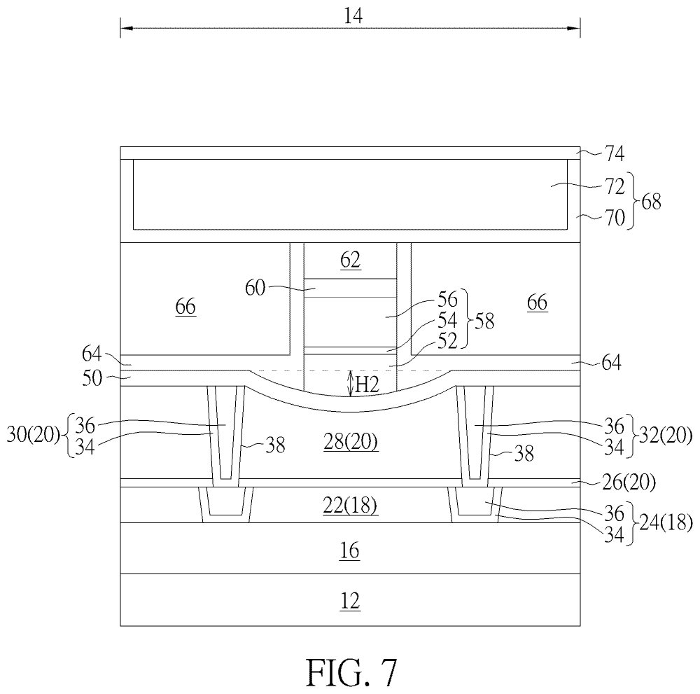

Referring to FIG. 7, FIG. 7 further illustrates a structural view of a MRAM device according to an embodiment of the present invention. As shown in FIG. 7, the MRAM device includes a SOT layer 50 disposed on the substrate 12, a MTJ 58 disposed on the SOT layer 50, a TE 62 disposed on the MTJ 58, and a cap layer 64 disposed on the SOT layer 50 and adjacent to the MTJ 58 and TE 62. In contrast to a BE 42 is disposed between the IMD layer 28 and SOT layer 50 in the aforementioned embodiment, the BE 42 is omitted is in this embodiment such that the SOT layer 50 would directly contact the IMD layer 28 underneath the MTJ 58 and metal interconnections 30, 32 adjacent to two sides of the MTJ 58.

Since no recess is formed directly on top of the metal interconnections 30, 32 to fill the BE 42 as disclose in the aforementioned embodiment, the top surface of the metal interconnections 30, 32 in this embodiment is preferably even with the top surface of the IMD layer 28 further away from the MTJ 58 but slightly higher than the top surface of the IMD layer 28 closer to the MTJ 58. Similar to the aforementioned embodiment, after the MTJ 58 is formed, the bottom surface of the SOT layer 50 directly under the MTJ 58 includes a curved surface, the top surface of the SOT layer 50 includes a curved surface, and the bottom surface of the MTJ 58 includes a curved surface. The top surface of the MTJ 58, the bottom surface of the TE 62, and the top surface of the TE 62 on the other hand all include planar surfaces. Nevertheless, according to other embodiment of the present invention, the top surface of the MTJ 58, the bottom surface of the TE 62, and the top surface of the TE 62 could also be formed with a curved surface concave upward as the SOT layer 50 depending on the demand of the product, which is also within the scope of the present invention. Moreover, since the top surface of the IMD layer 28 is formed into a curved surface concave upward so that the bottom of the MTJ 58 or bottom of the free layer 52 is now slightly lower than the top surface of the metal interconnections 30, 32 or top surface of the SOT layer 50 on two adjacent sides, a height H2 is measured between the bottom surface of the MTJ 58 and the top surface of the SOT layer 50 directly on top of the metal interconnections 30, 32 adjacent to two sides of the MTJ 58 at this stage. In this embodiment, H2 is slightly less than the aforementioned H1 as H2 is preferably between 5-20 Angstroms.

Overall, the present invention discloses a SOT MRAM device, which preferably deposits an IMD layer 28 and as a top surface of the IMD layer 28 forms a curve concave upward as a result of dishing phenomenon, the bottom surface and/or top surface of the BE 42, SOT layer 50, and MTJ formed thereafter also demonstrates similar curved surfaces. By forming curved surfaces on bottom surface and/or top surface of the BE, SOT layer and even part of the MTJ, it would be desirable to increase overall stress or strain of the device thereby improving tunnel magnetoresistance (TMR) performance of the device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a magnetoresistive random access memory (MRAM) device, comprising:
forming a spin orbit torque (SOT) layer on a substrate; and
forming a magnetic tunneling junction (MTJ) on the SOT layer, wherein a bottom surface of the MTJ comprises a first curve.

2. The method of claim 1, further comprising:
forming an inter-metal dielectric (IMD) layer on the substrate;
forming a first metal interconnection and a second metal interconnection in the IMD layer;
forming the SOT layer on the first metal interconnection and the second metal interconnection;
forming a top electrode (TE) on the MTJ; and
forming a cap layer on the MTJ and the SOT layer.

3. The method of claim 2, further comprising forming a bottom electrode (BE) on the first metal interconnection and the second metal interconnection before forming the SOT layer.

4. The method of claim 3, wherein a bottom surface of the BE comprises a second curve.

5. The method of claim 3, wherein a bottom surface of the BE under the MTJ is lower than a bottom surface of the BE on the first metal interconnection.

6. The method of claim 1, wherein a bottom surface of the SOT layer comprises a third curve.

7. The method of claim 1, wherein a bottom surface of the SOT layer under the MTJ is lower than a bottom surface of the SOT layer on the first metal interconnection.

8. A magnetoresistive random access memory (MRAM) device, comprising:
a spin orbit torque (SOT) layer on a substrate; and
a magnetic tunneling junction (MTJ) on the SOT layer, wherein a bottom surface of the MTJ comprises a first curve.

9. The MRAM device of claim 8, further comprising:
an inter-metal dielectric (IMD) layer on the substrate;
a first metal interconnection and a second metal interconnection in the IMD layer;
the SOT layer on the first metal interconnection and the second metal interconnection;
a top electrode (TE) on the MTJ; and
a cap layer adjacent to the MTJ.

10. The MRAM device of claim 9, further comprising a bottom electrode (BE) between the IMD layer and the SOT layer.

11. The MRAM device of claim 10, wherein a bottom surface of the BE comprises a second curve.

12. The MRAM device of claim 10, wherein a bottom surface of the BE under the MTJ is lower than a bottom surface of the BE on the first metal interconnection.

13. The MRAM device of claim 8, wherein a bottom surface of the SOT layer comprises a third curve.

14. The MRAM device of claim 8, wherein a bottom surface of the SOT layer under the MTJ is lower than a bottom surface of the SOT layer on the first metal interconnection.
